(19) United States
(12) Patent Application Publication
(10) Pub. No.: US 2025/0210504 A1
(43) Pub. Date: Jun. 26, 2025

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventor: Masashi ISHII, Ibo Hyogo (JP)

(73) Assignees: KABUSHIKI KAISHA TOSHIBA, Tokyo (JP); Toshiba Electronic Devices & Storage Corporation, Tokyo (JP)

(21) Appl. No.: 19/077,248

(22) Filed: Mar. 12, 2025

Related U.S. Application Data
(63) Continuation of application No. PCT/JP2024/007592, filed on Feb. 29, 2024.

(30) Foreign Application Priority Data
Jul. 14, 2023 (JP) 2023-115939

(51) Int. Cl. H01L 23/498; H01L 21/48; H01L 21/60; H01L 23/00; H01L 23/053; H01L 23/31; H01L 23/538; H01L 25/07; H05K 1/18; H10D 80/20

(52) U.S. Cl. CPC H01L 23/49838; H01L 23/053; H01L 23/5385; H01L 24/48; H05K 1/181; H01L 21/4853; H01L 2021/60195; H01L 23/3121; H01L 24/49; H01L 25/072; H01L 2224/48091; H01L 2224/48137; H01L 2224/48225; H01L 2224/49175; H01L 2924/13055; H10D 80/20

(57) ABSTRACT

According to one embodiment, a semiconductor device includes: a substrate; a case provided on the substrate and including a resin layer and a terminal; and a circuit board provided on the substrate and including a semiconductor chip and a wiring electrically connected to the semiconductor chip and the terminal, wherein the terminal includes a first portion extending from the resin layer toward the circuit board, a second portion bonded to the wiring, and a third portion between the first portion and the second portion, and the third portion is recessed toward an opposite side of a side of the substrate from the second portion.

### CROSS-REFERENCE TO RELATED APPLICATIONS

This application is a Continuation Application of PCT Application No. PCT/JP2024/007592, filed Feb. 29, 2024 and based upon and claiming the benefit of priority from Japanese Patent Application No. 2023-115939, filed Jul. 14, 2023, the entire contents of all of which are incorporated herein by reference.

### FIELD

Embodiments described herein relate generally to a semiconductor device.

### BACKGROUND

As a semiconductor device that implements a high output, a power module is known. The power module is constituted as one package in which a plurality of power semiconductors are integrated.

### BRIEF DESCRIPTION OF THE DRAWINGS

FIG. 1 is a perspective view showing the outer appearance of a semiconductor device according to the embodiment.

FIG. 2 is a plan view showing the internal structure of the semiconductor device according to the embodiment.

FIG. 3 is a sectional view showing the internal structure of the semiconductor device according to the embodiment.

FIG. 4 is a sectional view showing an example of the structure of the signal terminal and the case of the semiconductor device according to the embodiment.

FIG. 5 is a sectional view showing the example of the structure of the signal terminal and the case of the semiconductor device according to the embodiment.

FIG. 6 is a sectional view showing an example of the structure of the signal terminal of the semiconductor device according to the embodiment.

FIG. 7 is a sectional view showing one step of a manufacturing method of the semiconductor device according to the embodiment.

FIG. 8 is a sectional view showing one step of the manufacturing method of the semiconductor device according to the embodiment.

FIG. 9 is a sectional view showing a modification of the semiconductor device according to the embodiment.

### DETAILED DESCRIPTION

In general, according to one embodiment, a semiconductor device includes: a substrate; a case provided on the substrate and including a resin layer and a terminal; and a circuit board provided on the substrate and including a semiconductor chip and a wiring electrically connected to the semiconductor chip and the terminal, wherein the terminal includes a first portion extending from the resin layer toward the circuit board, a second portion bonded to the wiring, and a third portion between the first portion and the second portion, and the third portion is recessed toward an opposite side of a side of the substrate from the second portion.

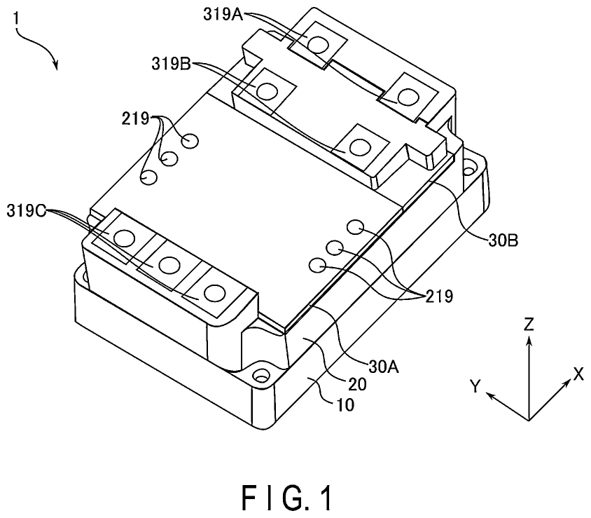

A semiconductor device according to the embodiment will be described with reference to FIGS. 1, 2, 3, 4, 5, 6, 7, 8, and 9. In the following explanation, the same reference numerals denote elements having the same functions and configurations. Also, in each of the following embodiments, if constituent elements (for example, circuits, interconnects, and various kinds of voltages and signals) denoted by reference numerals with numbers/characters for discrimination added at the end need not be discriminated from each other, expressions (reference numerals) without the numbers/characters at the end are used. Dimensions and ratios of constituent elements in the drawings do not necessarily match the actuality.

### Embodiments

### (1) Arrangement Example

With reference to FIGS. 1, 2, 3, 4, 5, and 6, an example of the arrangement of a semiconductor device according to the embodiment will be described.

FIG. 1 is a perspective view showing the outer appearance of a semiconductor device 1 according to this embodiment.

As shown in FIG. 1, the semiconductor device 1 according to the embodiment includes a base substrate 10, a case 20, lids 30A and 30B, and a plurality of connectors 219 and 319 (319A, 319B, and 319C).

The base substrate 10, the case 20, and the lids 30A and 30B form the container of the semiconductor device 1. Components including a semiconductor element are provided in the container of the semiconductor device 1.

The base substrate 10 is a support body of the semiconductor device 1. The base substrate 10 has a flat plate shape. The base substrate 10 corresponds to the bottom portion of the container of the semiconductor device 1. The base substrate 10 includes, for example, screw holes. The base substrate 10 can be fixed to an external apparatus of the semiconductor device 1 via the screw holes. The base substrate 10 can function as, for example, a heat sink. For example, the base substrate 10 includes (contains) copper and/or ceramic.

The case 20 is provided on the upper surface of the base substrate 10. The case 20 is an insulator having a rectangular cylindrical shape. The case 20 corresponds to the side portion of the container of the semiconductor device 1. The case 20 is fixed to the base substrate 10. For example, the case 20 is adhered to the base substrate 10 with an adhesive (resin). The case 20 is a resin member. For example, the case 20 includes Poly-Phenylene Sulfide (PPS).

The lids 30A and 30B are provided on the upper surface of the case 20. Each lid 30 is a plate-shaped insulator. The lids 30A and 30B correspond to the upper portion of the container of the semiconductor device 1. The lids 30 are fixed to the case 20. For example, the lids 30A and 30B contain PPS.

When the above-described base substrate 10, case 20, and lids 30A and 30B are assembled, a space to arrange components (for example, a semiconductor element) is formed inside the container of the semiconductor device 1. In the following description, a plane parallel to the contact surface between the base substrate 10 and the case 20 is defined as an X-Y plane. In the X-Y plane, the direction of one side of the base substrate 10 is an X direction, and the direction of the other side intersecting the one direction of the base substrate 10 is a Y direction. A direction perpendicular to the X-Y plane is a Z direction.

The semiconductor device 1 includes the plurality of connectors 219 and 319 (319A, 319B, and 319C). Each of the plurality of connectors 219 and 319 is electrically connected to the external apparatus of the semiconductor device 1. Each of the plurality of connectors 219 and 319 is electrically connected to the semiconductor element in the container of the semiconductor device 1. Each of the connectors 219 and 319 is an end portion of each terminal (bus bar) in the container of the semiconductor device 1.

The connector 319 is used for input/output of voltage and/or current to/from the semiconductor device 1. The connector 319 supplies a voltage (or current) from the external apparatus of the semiconductor device 1 to the semiconductor element in the container of the semiconductor device 1, or supplies a voltage (or current) generated by the semiconductor device 1 to the external apparatus.

For example, two connectors 319A are arranged in the Y direction in the upper portion of the semiconductor device 1 (for example, the upper surface of the case 20). The two connectors 319A correspond to P (Positive) polarity input terminals. The two connectors 319A are electrically connected to each other.

For example, two connectors 319B are arranged in the Y direction in the upper portion of the semiconductor device 1 (for example, the upper surface of the lid 30B). The two connectors 319B correspond to N (Negative) polarity input terminals. The two connectors 319B are electrically connected to each other.

For example, three connectors 319C are arranged in the Y direction in the upper portion of the semiconductor device 1 (for example, the upper surface of the case 20). The three connectors 319C correspond to output terminals. The three connectors 319C are electrically connected to each other.

The connector 219 is used to monitor the operating state of the semiconductor device 1. The connector 219 supplies, to the external apparatus of the semiconductor device 1, a signal indicating the monitoring result corresponding to the operating state of the semiconductor element in the container of the semiconductor device 1. Note that the connector 219 may be used to supply a control signal of the semiconductor device 1. For example, the connector 219 for control supplies a control signal from the external apparatus of the semiconductor device 1 to the semiconductor element in the container of the semiconductor device 1.

For example, three connectors 219 are arranged in the X direction in the upper portion of the semiconductor device 1 (for example, the upper surfaces of the case 20 and the lids 30). The three connectors 219 are electrically separated from each other.

One or more semiconductor chips constituting the semiconductor element are provided in the space surrounded by the base substrate 10, the case 20, and the lids 30.

The semiconductor device 1 according to this embodiment is a power module. For example, the semiconductor device 1 is an inverter, a converter, a regulator, a switch, or the like.

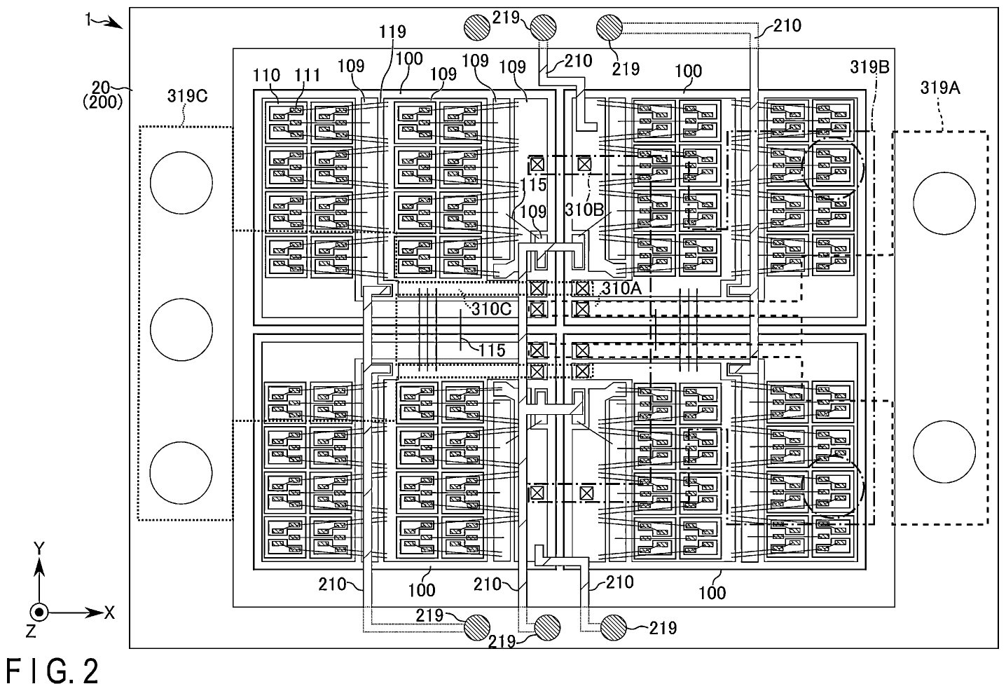

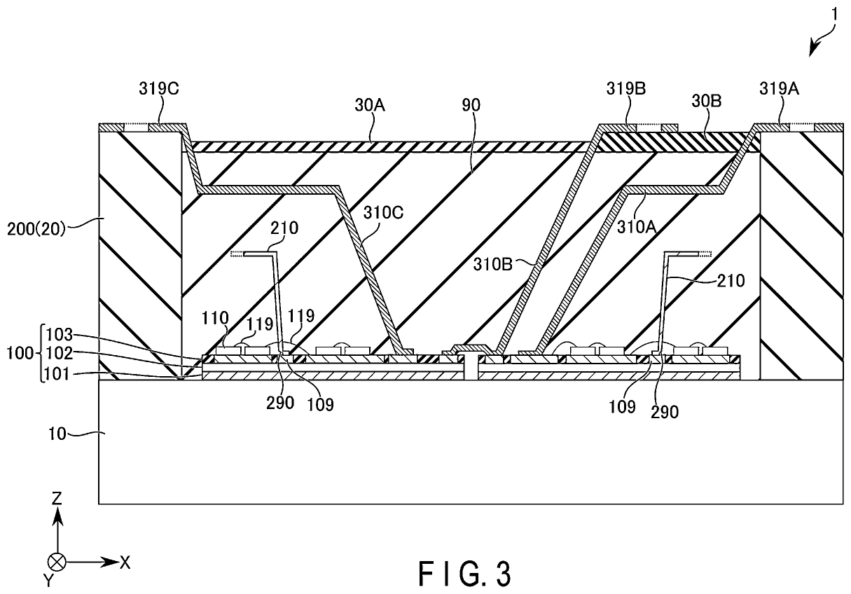

With reference to FIGS. 2 and 3, the internal structure of the semiconductor device 1 according to this embodiment will be described.

FIG. 2 is a plan view showing an example of the internal structure of the semiconductor device 1 according to this embodiment. FIG. 3 is a sectional view schematically showing the example of the internal structure of the semiconductor device 1 according to this embodiment. In FIG. 2, the connectors 319 arranged above the base substrate 10 are indicated by a dashed line, a dotted line, an alternate long and short dashed line, and the like.

As shown in FIGS. 2 and 3, the case 20 surrounds the space on the upper surface of the base substrate 10. The case 20 includes a rectangular cylindrical resin layer 200. For example, the space on the base substrate 10 surrounded by the case 20 is filled with an insulator (sealing material) 90.

The semiconductor device 1 according to this embodiment includes a plurality of semiconductor chips 110 provided on a circuit board 100. The number of the semiconductor chips 110 of one semiconductor device 1 is, for example, ten or more,

For example, four circuit boards 100 are provided on the base substrate 10. Each circuit board 100 is fixed to the base substrate 10 via solder (not shown) or an adhesive (not shown). The circuit boards 100 and the semiconductor chips 110 are sealed by the insulator (sealing material) 90.

The circuit board 100 includes two wiring layers 101 and 103 and an insulating layer 102. The insulating layer 102 is sandwiched between the two wiring layers 101 and 103. The wiring layers 101 and 103 include a plurality of wirings 109. The wiring 109 is a copper layer (Cu layer). The insulating layer 102 is a ceramic layer. For example, the wiring layer 103 is electrically separated from the wiring layer 101 by the ceramic layer 102. However, the wiring layer 103 on the upper surface side of the ceramic layer 102 may be electrically connected to the wiring layer 101 on the lower surface side of the insulating layer 102 via a through electrode (or plug) (not shown) in the insulating layer 102.

For example, two wirings 109 in the circuit board 100 are electrically connected to each other via a bonding wire 115. For example, two wirings 109 of adjacent circuit boards 100 are electrically connected to each other via the bonding wire 115.

The plurality of semiconductor chips 110 are provided on each circuit board 100. For example, sixteen semiconductor chips 110 are provided on one circuit board 100.

The semiconductor chip 110 includes a plurality of nodes 111. Each node 111 is connected, via the bonding wire 119, the node 111 of another semiconductor chip 110 or corresponding one of the plurality of wirings 109 on the circuit board 100. The node 111 is, for example, a pad or an electrode.

For example, the semiconductor chip 110 includes an IGBT-FRD (Insulated gate bipolar transistor-fast recovery diode).

The circuit board 100 and the plurality of semiconductor chips 110 on the circuit board 100 form a semiconductor circuit. In this embodiment, a set of the circuit board 100 and the semiconductor chips 110 connected to the circuit board 100 is also referred to as a semiconductor circuit.

A plurality of terminals (bus bars) 210 and 310 are provided in the container of the semiconductor device 1.

Each terminal 210 or 310 is a plate-shaped conductor. Each terminal 210 or 310 includes copper. One end (lower end) of each terminal 210 or 310 is electrically connected to the semiconductor chip 110 via the wiring 109 of the circuit board 100. The other end (upper end) of each terminal 210 or 310 is electrically connected to corresponding one of the plurality of connectors 219 and 319.

The terminals 310 (310A, 310B, and 310C) are terminals for input/output of voltage or current to/from the semiconductor chip 110. In the following description, the terminals 310 are referred to as input/output terminals. The input/output terminal 310A is electrically connected to the connector 319A. The input/output terminal 310A is a P polarity input terminal. The input/output terminal 310B is electrically connected to the connector 319B. The input/output terminal 310B is an N polarity input terminal. The input/output terminal 310C is electrically connected to the connector 319C. The input/output terminal 310C is an output terminal.

Each input/output terminal 310 is electrically connected to the corresponding wiring of the plurality of wirings 109 on the circuit board 100. In the Z direction, the end portion (upper end) of the input/output terminal 310 on the lid 30 side is arranged above the end portion (upper end) of the terminal 210 on the lid 30 side.

The terminals 210 are terminals for monitoring or controlling the semiconductor device 1. In the following description, the terminals 210 are referred to as signal terminals. Each signal terminal 210 is electrically connected to the corresponding connector 219. The signal terminal 210 is a conductor insert-molded in the case 20 (resin layer 200). For example, the signal terminal 210 is connected to the wiring 109 connected to the control terminal (for example, gate) and/or current path (for example, source/drain, emitter, or collector) of a transistor included in the semiconductor device 1.

The end portion (lower end or tip) of the signal terminal 210 on the circuit board 100 side is bonded to the wiring 109 of the wiring layer 103. With this, the signal terminal 210 is electrically connected to the semiconductor chip 110 via the wiring 109 and the bonding wire 119.

In the semiconductor device 1 according to this embodiment, the surface (bottom surface) of the signal terminal 210 which is in contact with the wiring 109 includes a step (recess) 290.

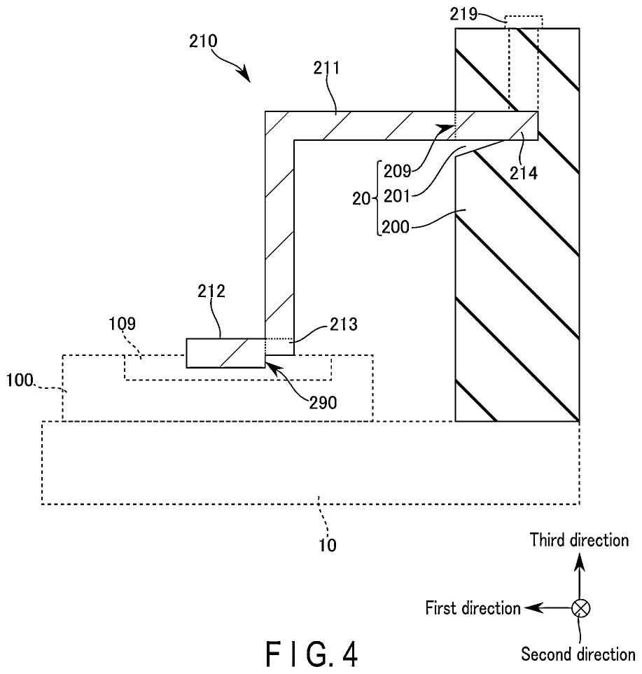

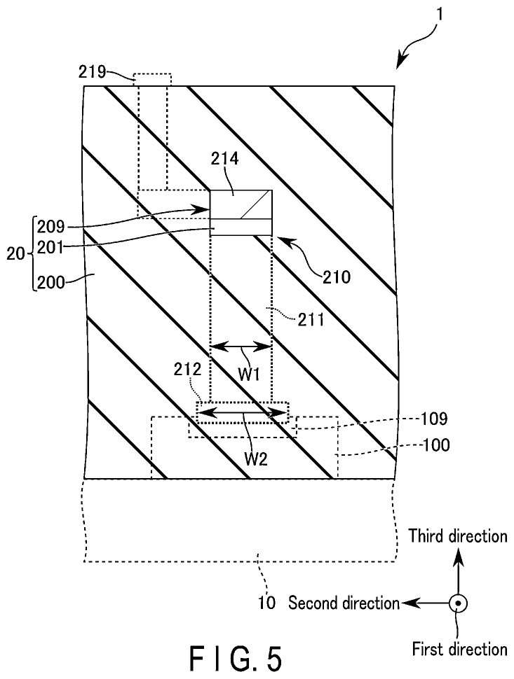

With reference to FIGS. 4 and 5, the structure of the signal terminal 210 and the case 20 of the semiconductor device 1 according to this embodiment will be described. FIG. 4 is a sectional view schematically showing the basic arrangement of the structure of the case 20 and the signal terminal 210 in the extending direction (first direction) of the signal terminal 210 in the semiconductor device 1 according to this embodiment. FIG. 5 is a sectional view schematically showing the basic arrangement of the structure of the case 20 and the signal terminal 210 in a direction (second direction) intersecting the extending direction of the signal terminal 210 in the semiconductor device 1 according to this embodiment. FIG. 5 shows a section of the opening portion of the resin layer 200 in the portion of the case 20 where the signal terminal is inserted. FIGS. 4 and 5 schematically show the base substrate 10 and the circuit board 100.

As shown in FIGS. 4 and 5, the case 20 includes a slit 201 between a portion 214 of the signal terminal 210 and the resin layer 200 in a region in the vicinity of the opening portion 209 for bringing out the signal terminal 210 in the resin layer 200 from the region layer 200 to the inside of the container.

The slit 201 has a wedge-shaped sectional shape. Note that the sectional shape of the slit 201 is not limited to the wedged shape, but may be a quadrilateral shape. Due to the slit 201, the dimension of the opening portion 209 in the third direction (Z direction) is larger than the thickness (the dimension in the third direction) of the plate-shaped portion of the signal terminal 210 in the resin layer 200.

By providing the slit 201 in the resin layer 200, the movable range of the signal terminal 210 toward the base substrate 10 side is increased in a case when a pressure toward the base substrate 10 side is applied to the signal terminal 210. In addition, the spring property of the signal terminal 210 in the portion protruding from the resin layer 200 improves.

The signal terminal 210 extends from the case 20 toward the circuit board 100. The signal terminal 210 includes a plurality of portions 211, 212, 213, and 214. In the following description, the portion 214 of the signal terminal 210 in the resin layer 200 of the case 20 is referred to as an insert portion (or embedded portion). The portion 212 of the signal terminal 210 that is bonded to the wiring 109 of the circuit board 100 is referred to as a bonding portion (or foot portion). The portion 211 of the signal terminal 210 extending from the insert portion 214 to the bonding portion 212 is referred to as a leg portion (or lead portion). The portion 213 of the signal terminal 210 connected to the lower end of the leg portion 211 and existing between the leg portion 211 and the bonding portion 212 is referred to as a heel portion.

The leg portion 211, the bonding portion 212, the heel portion 213, and the insert portion 214 constitute one continuous plate-shaped conductor.

The insert portion 214 is covered with the resin layer 200. One end of the insert portion 214 is connected to the leg portion 211. The other end of the insert portion 214 is connected to the connector 219. The bottom portion of the insert portion 214 does not contact the resin layer 200 due to formation of the slit 201. For example, in the assembled semiconductor device 1, the slit 201 between the bottom portion of the insert portion 214 and the resin layer 200 is filled with the insulator 90.

The portions 211, 212, and 213 of the signal terminal 210 protrude from the opening portion 209 of the resin layer 200 into the space (insulator 90) in the container of the semiconductor device 1. The leg portion 211, the bonding portion 212, and the heel portion 213 are exposed from the resin layer 200.

The heel portion 213 is provided between the led portion 211 and the bonding portion 212. The bonding portion 212 is connected to the leg portion 211 via the heel portion 213.

The bonding portion 212 is provided above the circuit board 100 in a direction (third direction) perpendicular to the upper surface of the base substrate 10. For example, a width W2 of the bonding portion 212 in the widthwise direction of the terminal 210 is larger than a width W1 of the leg portion 211 in the widthwise direction of the terminal 210.

In the semiconductor device 1 according to this embodiment, in the surfaces of the bonding portion 212 and heel portion 213 on the base substrate 10 side (the surfaces in contact with the wiring 109 or the bottom surface of the signal terminal 210), the step 290 is provided between the bonding portion 212 and the heel portion 213.

Due to the step 290, the bottom surface (the surface facing the wiring 109 or the surface on the base substrate 10 side) of the heel portion 213 is recessed from the bottom surface of the bonding portion 212 toward the lid 30 (the upper portion of the semiconductor device 1) side. Due to the step 290 of the heel portion 213, the signal terminal 210 has a spring property in the portion between the leg portion 211 and the bonding portion 212.

By providing the step 290 in the bottom portion (bottom surface) of the signal terminal 210, partial contact of the bottom portion of the signal terminal 210 with the circuit board 100 is suppressed.

The terminal having the shape shown in FIGS. 4 and 5 may be used as the voltage/current input/output terminal 310 for the semiconductor chip 110.

Note that, depending on the layout and shape of the signal terminal 210, the bonding portion 212 may be brought out from the led portion 211 (and the heel portion 213) in a direction (for example, second direction) intersecting the extending direction (for example, first direction) of the leg portion 211. Also in this case, the bonding portion 212 is connected to the leg portion 211 via the heel portion 213 located at the lower end of the leg portion 211. The leg portion 211 may extend in the second direction.

### Example of Structure of Terminal

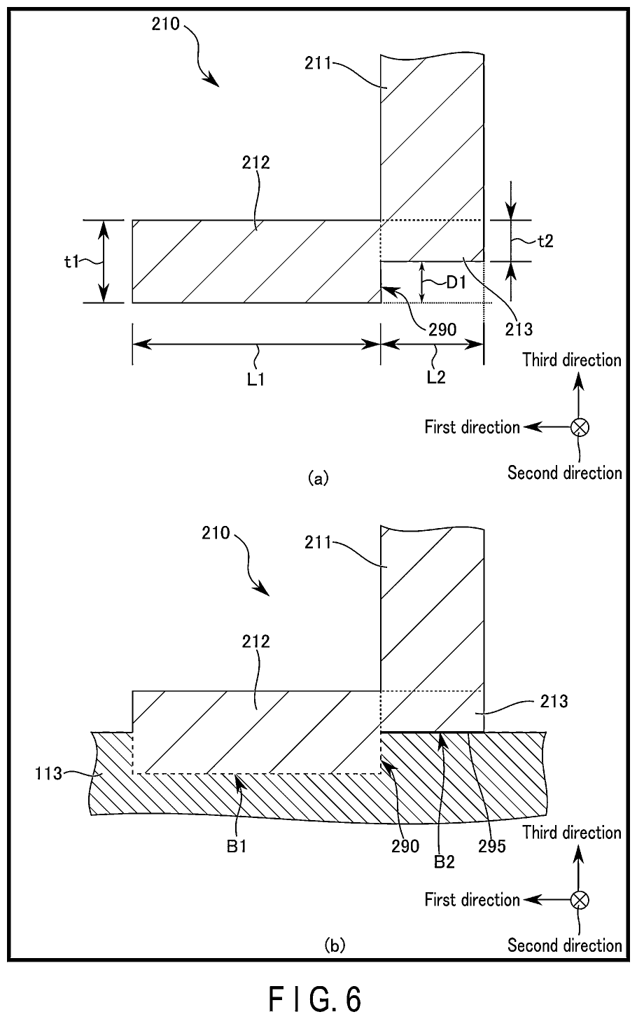

FIG. 6 is a schematic view showing a specific example of the shape of the signal terminal 210 in the semiconductor device 1 according to this embodiment. (a) of FIG. 6 is a sectional view showing an example of the specific structure of the signal terminal 210 in a state before bonding to the wiring 109 in the semiconductor device 1 according to this embodiment. (b) of FIG. 6 is a sectional view showing the example of the specific structure of the signal terminal 210 in a state after bonding to the wiring 109 in the semiconductor device 1 according to this embodiment.

As shown in (a) of FIG. 6, the signal terminal 210 includes the leg portion 211, the bonding portion 212, and the heel portion 213.

The leg portion 211 is a plate-shaped conductor. The leg portion 211 includes a portion extending from the case 20 (insert portion 214) toward the base substrate 10 in substantially a vertical direction. The leg portion 211 may be tilted with respect to the direction perpendicular to the upper surface of the base substrate 10.

The bonding portion 212 is a plate-shaped conductor. The bonding portion 212 extends in a direction parallel to the upper surface of the base substrate 10. The bonding portion 212 is connected to the leg portion 211 via the heel portion 213. The bonding portion 212 is a portion of the signal terminal 210 that is bonded to the wiring 109. The bonding portion 212 corresponds to the tip portion in the contact surface of the signal terminal 210 with respect to the wiring 109.

The dimension (length) of the boning portion 212 in the direction from the heel portion 213 toward the bonding portion 212 (the longitudinal direction of the bonding portion 212) is indicated by “L1”. The dimension (thickness) of the bonding portion 212 in the direction perpendicular to the surface of the base substrate 10 (the thickness direction of the bonding portion 212) is indicated by “t1”.

The heel portion 213 is a plate-shaped conductor. The heel portion 213 is located at the lower end of the leg portion 211. The heel portion 213 connects the bonding portion 212 to the leg portion 211. The bottom surface of the heel portion 213 is located closer to the upper portion side (lid 30 side) of the semiconductor device 1 than the bottom surface of the bonding portion 211. The heel portion 213 corresponds to the proximal region in the contact surface of the signal terminal 210 with respect to the wiring 109. Note that the heel portion 213 can be treated as the lower end portion of the leg portion 211.

The dimension (length) of the heel portion 213 in the direction from the heel portion 213 toward the bonding portion 212 is indicated by “L2”. For example, the dimension L2 of the heel portion 213 is smaller than the dimension L1 of the bonding portion 212. For example, the dimension L2 is equal to or less than half of the dimension L1.

The dimension (thickness) of the heel portion 213 in the direction perpendicular to the surface of the base substrate 10 (the thickness direction of the heel portion) is indicated by “t2”. The dimension t2 of the heel portion 213 is smaller than the dimension t1 of the bonding portion 212. For example, the dimension t2 is in the range of not less than one-third of the dimension t1 and not more than one-half of the dimension t1.

The step 290 is provided in a region (boundary portion) between the bonding portion 212 and the heel portion 213. The size of the step 290 is indicated by “D1”. The size D1 of the step corresponds to the difference value (t1−t2) between the thickness t1 and the thickness t2. As a result, in the semiconductor device 1 according to this embodiment, the signal terminal 210 has a structure in which the heel portion 213 of the signal terminal 210 is recessed from the bonding portion 212 toward the lid 30 side of the semiconductor device 1.

For example, the step 290 between the bonding portion 212 and the heel portion 213 is formed by striking the heel portion 213 with a die or polishing the member of the heel portion 213.

As shown in (b) of FIG. 6, the signal terminal 210 and the wiring 109 are bonded by application of an ultrasonic wave and a pressure. If each of the signal terminal 210 and the wiring 109 is formed of copper, the bonding portion 212 and the wiring 109 are bonded by Cu—Cu bonding due to application of an ultrasonic wave and a pressure.

If the signal terminal 210 is bonded to the wiring 109 on the circuit board 100 by Cu—Cu bonding using an ultrasonic wave, the bonding portion 212 is integrated with the wiring 109. Due to the high-speed vibration of the applied ultrasonic wave, interatomic bonding occurs between the bonding portion 212 and the wiring 109. Accordingly, the bonding portion 212 and the wiring 109 become a conductor having an unclear boundary (interface) B1 (having substantially no boundary) between the bonding portion 212 and the wiring 109. However, depending on the difference between the composition ratio of the member of the signal terminal 210 and the composition ratio of the member of the wiring 109, the boundary B1 between the signal terminal 210 and the wiring 109 may be distinguishable.

For example, the bottom portion (bottom surface) of the bonding portion 212 sinks into the wiring 109 due to the pressure applied during ultrasonic bonding. In accordance with the sink of the bonding portion 212, the upper surface of the wiring 109 is recessed in the contact region between the bonding portion 212 and the wiring 109.

Note that in the contact region between the bonding portion 212 and the wiring 109, the position of the upper surface of the wiring 109 may be maintained and the bonding portion 212 may be crushed. If the bonding portion 212 is crushed, the dimension of the bonding portion 212 on the lower surface (bottom surface or contact surface) side is larger than the width of the bonding portion 212 on the upper surface side.

For example, the influence of the ultrasonic wave and pressure in the heel portion 213 is small as compared to the influence of the ultrasonic wave and pressure in the bonding portion 212. In this case, the heel portion 213 and the wiring 109 are not integrated. The heel portion 213 only contacts the wiring 109. For example, a boundary (interface) B2 exists between the heel portion 213 and the wiring 109. In some cases, an insulating layer 295 made of an oxide or the like is provided between the heel portion 213 and the wiring 109. However, similar to the bonding portion 212, the heel portion 213 and the wiring 109 may be integrated into one conductor.

As described above, in the semiconductor device 1 according to this embodiment, in the signal terminal 210 including the step 290 in the bonding surface with the wiring 109, the tip portion (bonding portion) 212 of the signal terminal 210 can be bonded to the wiring 109 of the circuit board 100.

### (2) Manufacturing Method

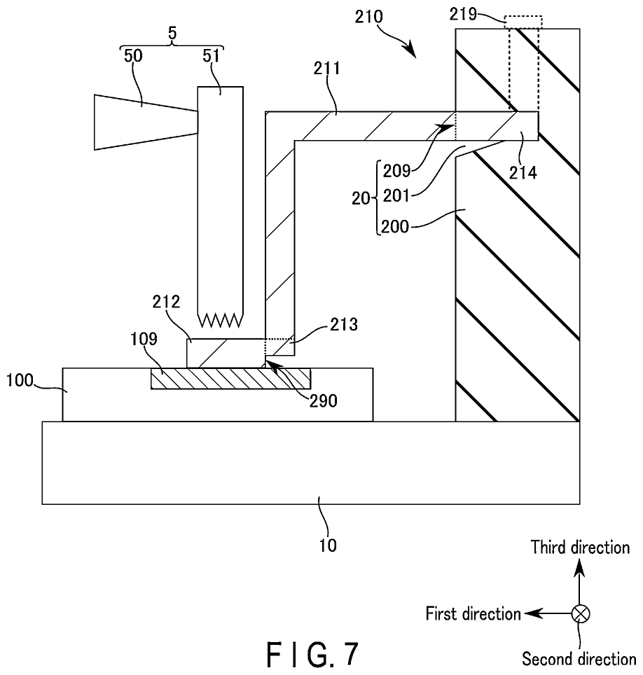

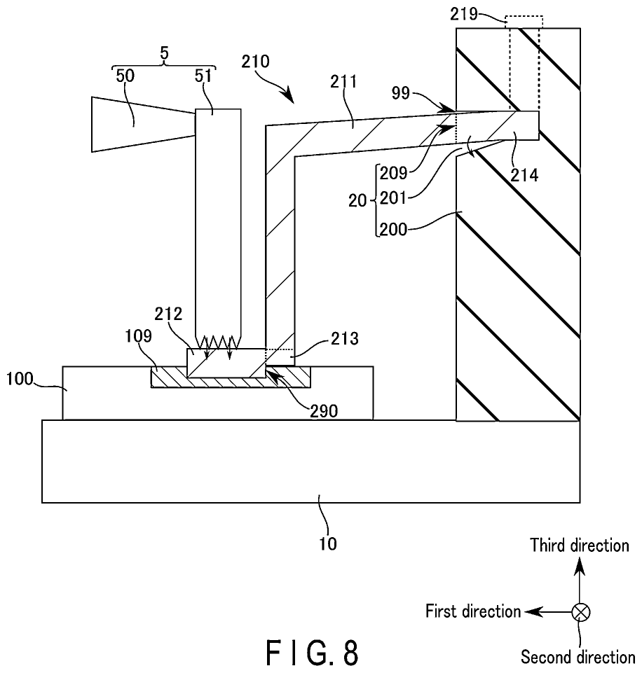

With reference to FIGS. 7 and 8, a manufacturing method of the semiconductor device 1 according to this embodiment will be described. FIGS. 7 and 8 are sectional views each showing one step of the manufacturing method of the semiconductor device 1 according to this embodiment.

As shown in FIG. 7, in an assembly step of the semiconductor device (power module) 1, the circuit board 100 including the plurality of semiconductor chips 110 is arranged on the base substrate 10. The case 20 including the insert-molded signal terminals 210 is arranged on the base substrate 10.

In order to bond the signal terminal 210 of the case 20 to the wiring 109 of the circuit board 100, the base substrate 10 with the circuit board 100 and the case 20 arranged thereon is mounted in an ultrasonic device 5.

The bonding portion 212 of the signal terminal 210 is arranged on the wiring 109 such that the position of the bonding portion 212 matches the position of the corresponding wiring 109 of the circuit board 100.

At this time, as in this embodiment, since the heel portion 213 of the signal terminal 210 is recessed, occurrence of a partial contact of the heel portion 213 of the signal terminal 210 is suppressed.

Therefore, in this embodiment, the bottom surface of the bonding portion 212 of the signal terminal 210 contacts the wiring 109 almost parallel thereto.

In the ultrasonic device 5, an ultrasonic capillary 51 connected to an ultrasonic horn 50 is brought into contact with the signal terminal 210. The ultrasonic horn 50 generates an ultrasonic wave having a certain amplitude and a certain frequency. The ultrasonic capillary 51 supplies the ultrasonic wave from the ultrasonic horn 50 to the signal terminal 210, and applies a pressure to the signal terminal 210.

As shown in FIG. 8, to supply the ultrasonic wave to the signal terminal 210, the ultrasonic capillary 51 is pressed against the bonding portion 212 of the signal terminal 210. Due to the vibration of the ultrasonic wave and pressurization by the ultrasonic capillary 51, the bonding portion 212 of the signal terminal 210 is bonded to the wiring 109.

When the ultrasonic capillary 51 is pressed against the signal terminal 210, the signal terminal 210 is lowered toward the base substrate 10.

In this embodiment, the wedge-shaped slit 201 is provided between the resin layer 200 and the bottom portion (bottom surface) of the insert portion 214 of the signal terminal 210 in the opening portion 209 of the case 20 on the signal terminal 210 side. This increases the movable range of the signal terminal 210, thereby improving the spring property of the signal terminal 210. As a result, in this embodiment, bending of the signal terminal 210 toward the base substrate side increases as compared to a case without the slit 201.

Therefore, when the ultrasonic capillary 51 applies a pressure to the signal terminal 210 toward the base substrate 10 side, the signal terminal 210 insert-molded in the case 20 is sufficiently pressure-bonded to the wiring 109. As a result, in this embodiment, the bonding portion 212 of the signal terminal 210 can be securely bonded to the wiring 109.

Accordingly, in this embodiment, occurrence of a bonding failure between the signal terminal 210 and the wiring 109, which is caused by a partial contact of the bottom portion of the signal terminal 210 with the circuit board 100, is suppressed.

Note that if the signal terminal 210 is bent toward the base substrate 10 side due to pressing by the ultrasonic capillary 51, a gap 99 may be generated between the upper portion of the insert portion 214 and the resin layer 200. The gap 99 can remain in the semiconductor device 1 even after completion of the manufacturing step of the semiconductor device 1.

As shown in (b) of FIG. 6, the bonding portion 212 of the signal terminal 210 is integrated with the wiring 109 by Cu—Cu bonding due to application of the ultrasonic wave and application of the pressure.

After each signal terminal 210 is bonded to the corresponding wiring 109, the plurality of input/output terminals 310 are arranged on the case 20. Each input/output terminal 310 is bonded to the corresponding wiring 109 on the circuit board 100 by, for example, ultrasonic bonding. After the input/output terminals 310 are bonded to the wirings 109, the lids 30 are connected to the case 20. The insulator 90 is filled into the case 20.

By the steps described above, the semiconductor device 1 according to this embodiment is completed.

### (3) Modification

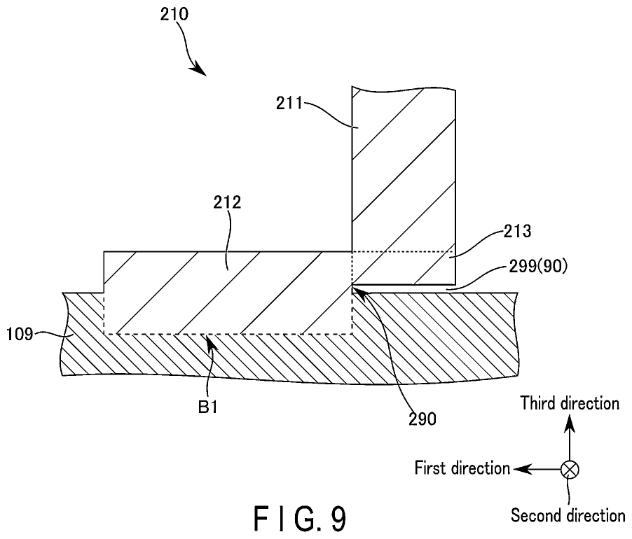

FIG. 9 is a sectional view showing a modification of the semiconductor device according to this embodiment. As shown in FIG. 9, a gap 299 may be provided between the heel portion 213 of the signal terminal 210 and the wiring 109 of the circuit board 100. For example, after the semiconductor device 1 is assembled, the gap 299 is filled with the insulator 90. The insulator 90 is provided between the heel portion 213 and the wiring 109.

Also in this case, the semiconductor device 1 according to the modification can suppress a bonding failure between the signal terminal 210 and the wiring 109.

### (4) Summary

In a semiconductor device such as a power module, a terminal insert-molded in a case is bonded to a wiring of a circuit board on a base substrate.

When bonding the case and the base substrate, if the signal terminal (or case) is deformed due to an external force, the bonding portion of the signal terminal with the wiring may be raised above the wiring. If the bonding portion is raised above the wiring, the bottom portion of the signal terminal having a flat contact surface may come into partial contact with the wiring.

If ultrasonic bonding between the signal terminal and the wiring is executed while the bottom portion of the signal terminal is in partial contact with the wiring, since the contact area between the bottom portion of the signal terminal and the wiring is small, a bonding failure can occur between the signal terminal and the wiring.

In the semiconductor device 1 according to this embodiment, the heel portion 213 in the bottom portion of the signal terminal 210 is recessed. Due to the recess of the heel portion 213, the step 290 is provided between the heel portion 213 in the bottom surface of the signal terminal 210 and the bonding portion 212 which is to be bonded to the wiring 109.

In the semiconductor device 1 according to this embodiment, the step 290 allows a space to be provided between the wiring 109 and the heel portion 213 of the signal terminal 210 so as to avoid the partial contact of the signal terminal 210. Hence, in this embodiment, the lower end (heel portion 213) of the leg portion 211 of the signal terminal 210 is less likely to come into contact with the wiring 109 before the bonding portion 212 of the signal terminal 210 comes into contact with the wiring 109.

Accordingly, the semiconductor device 1 according to this embodiment can suppress occurrence of the partial contact in the heel portion 213 (the lower end of the leg portion 211) of the signal terminal 210.

The signal terminal close to the resin layer of the case has relatively high rigidity. If a signal terminal has high rigidity, the signal terminal is not easily bent.

In the semiconductor device 1 according to this embodiment, the wedge-shaped slit 201 is provided in the region between the resin layer 200 and the bottom portion of the insert portion 214 of the signal terminal 210 in the resin layer 200. This improves the spring property of the signal terminal 210 in the vicinity of the opening portion 209 of the resin layer 200 (the vicinity of the boundary between the leg portion 211 and the insert portion 214). In addition, arranging the slit 201 increases the movable range of the signal terminal 210 toward the base substrate 10 side. Therefore, in this embodiment, during the step of ultrasonic bonding, the signal terminal 210 can be largely bent toward the base substrate side.

As a result of these, in the semiconductor device 1 according to this embodiment, the contact surface of the signal terminal 210 with the wiring 109 (for example, the bottom surface of the bonding portion 212) and the wiring 109 can be brought into contact in parallel. Thus, the semiconductor device 1 according to this embodiment can execute ultrasonic bonding between the signal terminal 210 and the wiring 109 while ensuring the large contact surface between the signal terminal 210 and the wiring 109.

Accordingly, the semiconductor device 1 according to this embodiment can suppress a bonding failure between the signal terminal 210 and the wiring 109.

Furthermore, in this embodiment, if the signal terminal expands due to heat, a stress generated between the resin layer 200 and the signal terminal 210 can be reduced by the slit 201. Accordingly, the semiconductor device 1 according to this embodiment can suppress the stress-induced shape distortion and deterioration of the signal terminal.

As has been described above, the semiconductor device according to this embodiment can suppress a failure of the semiconductor device. Accordingly, the semiconductor device according to this embodiment can improve the manufacturing yield of the semiconductor device.

### (5) Others

The semiconductor device according to this embodiment is not limited to a power module as long as it is a device in which a terminal insert-molded in a case is bonded to a conductor on a substrate by ultrasonic bonding. Further, the device according to this embodiment is not limited to a semiconductor device as long as it is a device in which a terminal insert-molded in a case is bonded to a conductor on a substrate by ultrasonic bonding.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a case provided on the substrate and including a resin layer and a terminal; and
a circuit board provided on the substrate and including a semiconductor chip and a wiring electrically connected to the semiconductor chip and the terminal,
wherein
the terminal includes
a first portion extending from the resin layer toward the circuit board,
a second portion bonded to the wiring, and
a third portion between the first portion and the second portion, and
the third portion is recessed toward an opposite side of a side of the substrate from the second portion.

2. The semiconductor device according to claim 1, wherein
the terminal includes a step between the second portion and the third portion.

3. The semiconductor device according to claim 1, wherein
the terminal further includes a fourth portion provided in the resin layer, and
the case further includes a slit provided between the fourth portion and the resin layer.

4. The semiconductor device according to claim 3, further comprising an insulator covering the circuit board,
wherein the insulator is provided in the slit.

5. The semiconductor device according to claim 1, wherein
a dimension of the third portion in a first direction perpendicular to an upper surface of the substrate is smaller than a dimension of the second portion in the first direction.

6. The semiconductor device according to claim 1, wherein
a dimension of the second portion in a second direction parallel to an upper surface of the substrate is larger than a dimension of the third portion in the second direction.

7. The semiconductor device according to claim 1, wherein
a dimension of the second portion in a third direction parallel to an upper surface of the substrate is larger than a dimension of the first portion in the third direction.

8. The semiconductor device according to claim 1, wherein
the second portion is consecutive to the wiring.

9. The semiconductor device according to claim 1, wherein
the third portion is in contact with the wiring and is not consecutive to the wiring.

10. The semiconductor device according to claim 1, further comprising an insulator covering the circuit board,
wherein the insulator is provided between the third portion and the wiring.

11. The semiconductor device according to claim 1, wherein
the terminal is a conductor insert-molded in the resin layer.

12. A semiconductor device comprising:
a substrate;
a case provided on the substrate and including a resin layer, a terminal, and a slit provided between a portion of the terminal in the resin layer and the resin layer; and
a circuit board provided on the substrate and including a semiconductor chip and a wiring electrically connected to the semiconductor chip and the terminal.

13. The semiconductor device according to claim 12, wherein
the terminal is a conductor insert-molded in the resin layer.
